(19) United States
(12) Patent Application Publication
(10) Pub. No.: US 2014/0009893 A1
(43) Pub. Date: Jan. 9, 2014

(54) SERVER EQUIPPED WITH TOUCH DISPLAY MODULE AND TOUCH DISPLAY MODULE THEREOF

(71) Applicant: WISTRON CORP., NEW TAIPEI CITY (TW)

(72) Inventor: YUNG CHENG LAI, NEW TAIPEI CITY (TW)

(73) Assignee: WISTRON CORP., NEW TAIPEI CITY (TW)

(21) Appl. No.: 13/645,659

(22) Filed: Oct. 5, 2012

(30) Foreign Application Priority Data
Jul. 6, 2012 (TW) 101124398

(51) Int. Cl. H05K 7/14

(52) U.S. Cl. 361/728

(57) ABSTRACT

A server equipped with touch display module is illustrated. The server is placed in a rack enclosure and includes a rack, an information gathering unit, a rack connecting unit, and the touch display module. The rack includes a receiving slot in front side of the rack. The information gathering unit is coupled with a plurality of system components of the server and used for gathering operation information of the system components. The operation information is transmitted to the touch display module through the rack connecting unit. The touch display module slidably received in the receiving slot can be drawn out for displaying operation information. The operation information includes identification data and state data of the system components. When error information associated with the system component is identified in the received operation information, the touch display module drawn out displays an alert message related to the failed system component.

### BACKGROUND

1. Technical Field

The present disclosure is related to a server. In particular, the present disclosure relates to a server equipped with a touch display module.

2. Description of Related Art

Managers of servers usually need to monitor a lot of servers enclosed in rack enclosures (also known as “rack mounts”), and are responsible for discovering and fixing errors when the servers are malfunctioned, in order to keep the servers running successfully.

In order to assist the managers to monitor servers, it is commonly adapted to arrange a panel having multiple light units at the surface of a rack of the server and set multiple light units corresponding to system components in the server as described in U.S. Pat. No. 6,867,704. When one of the system components of a server is erroneous, the manager opens the rack of the server and identifies the malfunctioned system component and the cause of error by referring to the combinations of the light units on the panel and the light units in the server. Alternatively, as published in US Publication No. 2009/0150532, some may use external input-output devices and network to manage and monitor multiple servers.

However, the manner which the server manager refers to light units on the panel and in the server to detect the server problems costs server managers a lot of time and efforts. To put it concretely, the managers need to pull out and open the rack of the server, searching for the lighting light unit in the server in view of the lighting light unit on the panel to figure out the meaning of the lighting light unit. This approach also hardly provides clear information for managers to know the exact problem of the server at first sight, thus increasing the difficulties to recover the server. On the other hand, remote control via external input-output device and network requires extra devices outside servers, and at least one connection port on each server must be spared for connecting with the external input-output device. Besides, controlling servers via external input-output devices may only be used to monitor the current status of the servers but not available for adjusting operation settings of hardware components in the servers, and therefore, it may not be able to satisfy the requirements of the server managers.

### SUMMARY

The instant disclosure provides a server equipped with a touch display module. The server is placed in a rack enclosure and includes a rack, a information gathering unit, a rack connecting unit and the touch display module. The rack has a receiving slot arranged at a front side of the rack. The information gathering unit is mounted in the rack and connected with a plurality of system components of the server, and is used for gathering operation information of the plurality of the system components. The rack connecting unit is mounted in the rack and connected with the information gathering unit, and is used for transmitting the operation information to the touch display module. The touch display module further includes a base, a display connecting unit, a processing unit, and a touch panel module. The base is slidably received in the receiving slot. The display connection unit and the processing unit are arranged in the base, and the touch panel module is arranged at the top of the base. The display connecting unit connects to the rack connecting unit and receives the operation information through the rack connecting unit. The processing unit is connected with the display connecting unit for receiving and processing the operation information transmitted from the display connecting unit. The touch panel module is connected with the processing unit for displaying the operation information processed by the processing unit. The operation information includes identification data and at least a state data of the plurality of the system components, and when the state data includes an error information of the plurality of the system components, the processing unit outputs an alert message associated with the system component corresponding to the error information to the touch panel module.

The instant disclosure also provides a touch display module having corresponding elements which is adaptive to the above-mentioned server.

According to the instant disclosure, the server equipped with a touch display module and the touch display module thereof are able to display various operation information of the system components of a server. Server managers may review and control details of every system component via the touch display module, and thus efficiently monitor and manage servers.

For further understanding of the instant disclosure, reference is made to the following detailed description illustrating the embodiments and examples of the instant disclosure. The description is for illustrative purpose only and is not intended to limit the scope of the claim.

### BRIEF DESCRIPTION OF THE DRAWINGS

FIG. 1 is an external perspective view of a server equipped with a touch display module according to the present disclosure.

FIG. 2 is an internal perspective view of a server equipped with a touch display module according to the present disclosure.

FIG. 3 is an internal perspective view of a touch display module according to the present disclosure.

FIG. 4 is a block diagram of a server equipped with a touch display module according to the present disclosure.

FIGS. 5-7 are schematic diagrams for displaying operation information shown on display panel according to the present disclosure.

### DETAILED DESCRIPTION OF THE PREFERRED EMBODIMENTS

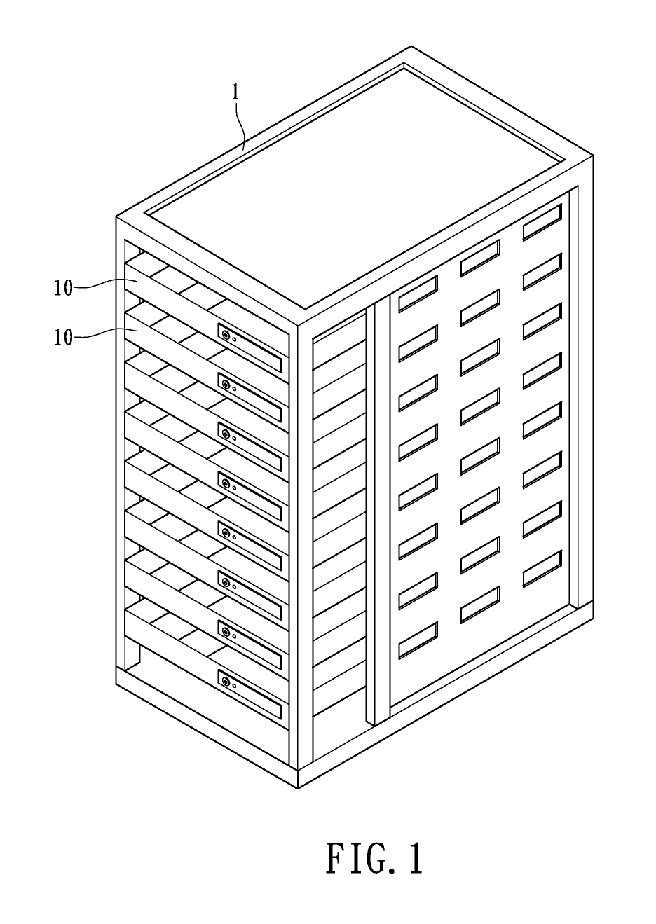

Please refer to FIG. 1, which is an external perspective view of a server equipped with a touch display module of the present embodiment. The server 10 is placed in a rack enclosure 1. One rack enclosure 1 is able to contain several servers 10.

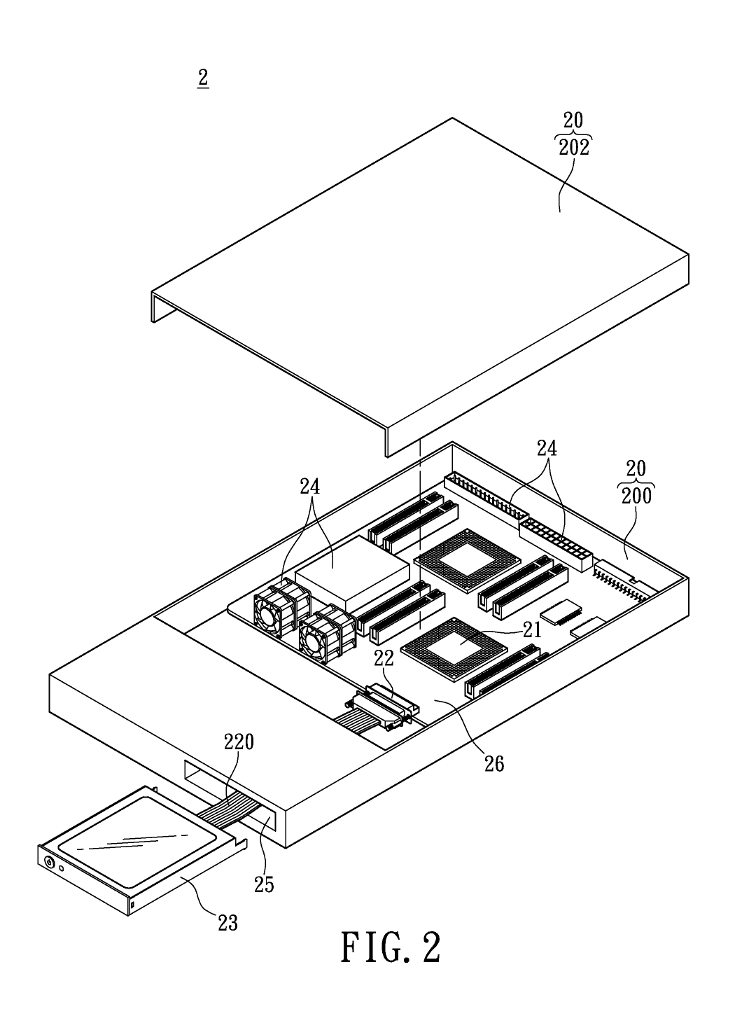

Please refer to FIG. 2, which is an internal perspective view of a server of the present embodiment. The server 2 in the embodiment includes a rack 20, an information gathering unit 21, a rack connecting unit 22, and a touch display module 23. Besides, the server 2 may also include a plurality of system components 24 for being monitored and managed, and a receiving slot 25 for receiving the touch display module 23. The information gathering unit 21, the rack connecting unit 22, the plurality of system components 2, and the receiving slot 25 are disposed on a body 200 of the rack 20. A cover 202 of the rack 20 may clasp the body 200 to cover the above-mentioned units or components within the rack 20. The information gathering unit 21 and the system components 25 are mounted on a server main board 26 in the rack 20. The system components 25 are also connected with the information gathering unit 21. The rack connecting unit 22 may be installed on the server main board 26, or alternatively, the rack connecting unit 22 may be connected with the server main board 26 and coupled to the information gathering unit 21 via a cable (not shown in FIG. 2). The receiving slot 25 is arranged at a front side of the rack 20 as shown in FIG. 2 and configured for receiving the touch display module 23. Therefore, a manager of the server 2 may draw out the touch display module 23 from the receiving slot 25 at the front side of the rack 20, so as to monitor operations of the server 2 or recover the server 2 from error by utilizing the touch display module 23.

The rack 20 in the present embodiment may be a server rack unit generally having 1.75 inches height, which is usually called 1 U rack. However the rack 20 is not limited to be a 1 U rack or have a height of 1.75 inches. The plurality of system components 24 may exemplarily include hardware devices like fan, hard drive, memory module, central processing unit, and/or power supply unit. The quantity of a same kind of hardware device in the server 2 may be more than just one. For example, there may be several fans, hard drives, memory modules, and even several central processing units in one server 2, wherein every single hardware device has a unique identification data. Therefore, multiple hardware devices may be regarded as multiple different system components even if the multiple hardware devices are a same kind device.

The information gathering unit 21 is used to collect and gather operation information of every system component 24 as mentioned above. The operation information of each system component 24 may include the identification data and a state data of the system component 24. The identification data may be device name, manufacturer name, product number, product type, or the combinations of any of the aforementioned data of the system component 24. The state data may exemplarily be the current temperature of a central processing unit, a fan, or a hard drive, speed of a fan, speed of a hard drive, total capacity and usable capacity of a hard drive, and so on. The information gathering unit 21 may be an application-specific integrated circuit (ASIC) implemented by logic circuit such as field programmable gate array (FPGA) or complex programmable logic device (CPLD). In addition to collect and gather operation information of the system components 24, the information gathering unit 21 may also be configured to receive an input command from the touch display module 23 and feedback the input command to a corresponding system component 24.

The rack connecting unit 22 is configured to electronically connected with the touch display module 23, in order to transceive information and commands between the information gathering unit 21 and the touch display module 23.

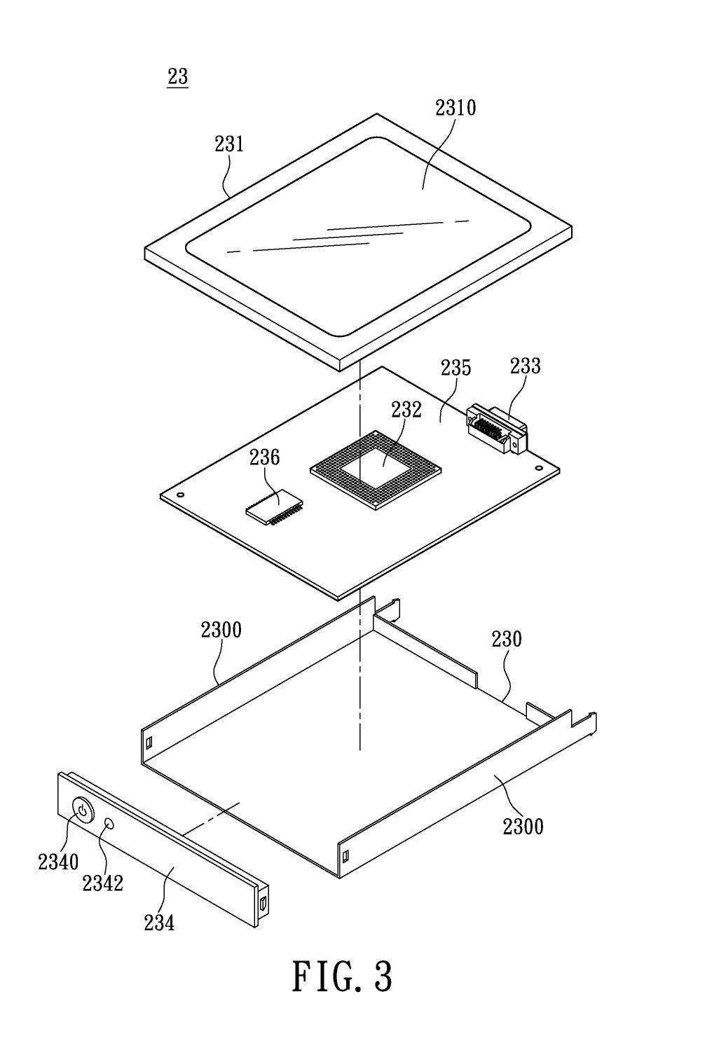

Please refer to FIG. 3 for a perspective view of the main elements of the touch display module 23 in the present embodiment. As shown in FIG. 3, the touch display module 23 may further include a base 230 slidably received in the receiving slot (labeled 25 in FIG. 2), a touch panel module 231, a processing unit 232, a display connecting unit 233 configured for connecting with the rack connecting unit 22 shown in FIG. 2, and a front panel 234. The processing unit 232 and the display connecting unit 233 may be mounted on a display module main board 235. The front panel 234 may be hooked with side bars 2300 set at two sides of the base 230 and therefore secured at a front side of the base 230. It should be understood by people skilled in the art that the touch display module 23 may include other components not illustrated in FIG. 3.

The shape and size of the base 230 is adaptive to the receiving slot 25. The base 230 may have sliding wheels (not shown in FIG. 3) set on both sides of the base 230 and slidably mounted on sliding tracks fixed in the receiving slot 25. The base 230 may then slide in or out of the receiving slot 25. Therefore, a server manager is able to draw out the touch display module 23 from the receiving slot 25 for using the touch display module 23, and push the touch display module 23 back into the receiving slot 25 when the touch display module 23 is not in-use. The base 230 may, for example, have a press part for triggering a button allocated in the receiving slot 25. When the server manager pushes the front panel 234 of the touch display module 23 received in the receiving slot 25, the button in the receiving slot 25 is triggered by the press part and springs the base 230, so that the server manager may draw or pull the touch display module 23 out of the receiving slot 25. People skilled in the art may modify the afore-mentioned exemplary approaches for enabling the base 230 to move back and forth in the receiving slot 25 or enabling the server manager to easily push and pull the touch display module 23.

The touch panel module 231 may be configured on a top side of the base 230. The touch panel module 231 further includes a display panel 2310 and a touch detecting module (not shown in FIG. 3). In addition to be an output device that outputs information to be shown on the display panel 2310, the touch panel module 231 may also be regarded as input device by generating input commands according to the touch detecting module detecting a user's operation of the display panel 2310.

The front panel 234 is configured on a front side of the base 230. A power button 2340 and an alert light 2342 (e.g. light emission diode, LED) are disposed on the front panel 234. The power button 2340 is used for turning on or turning off the display panel 2310, while the alert light 2342 is controlled by the processing unit 232 to flash or radiate when system components err. When the touch display module 23 is received in the receiving slot 25, the front panel 234 may be located at the opening of the receiving slot 25 and aligned with the front surface of the rack, and thus remain visible for the server manager. In other words, when a number of racks are piled in a rack enclosure, the server manager can see the front side of racks and front panel of the touch display modules of each server (as shown in FIG. 1). If any one of the servers goes wrong, the server manager may quickly identify the failed server via the flashing or radiating alert light 2342 on the front panel 234.

The processing unit 232 may be mounted on the display module main board 235 which is disposed in the base 230. The processing unit 232 is connected with touch panel module 231, display connecting unit 233, and the front panel 234. The processing unit 232 may exemplarily be a micro controller for receiving operation information of system components gathered by the information gathering unit (labeled 21 in FIG. 2). The processing unit 232 further processes and outputs the received operation information to the touch panel module 231, for demonstrating the operation information in a form of text, table, chart, image, or combinations thereof. The processing unit 232 may also receive and process the input command generated by the touch panel module 231, and controls to transmit processed result back to the information gathering unit. In particular, in order to output the operation information in the form of text, table, chart, image, or their combinations, the touch display module 23 may further includes firmware codes stored in a memory unit 236. The firmware codes are designed to be read and executed by the processing unit 232 for providing various operation information presentation styles on the display panel 2310. The memory unit 236 may be an electrically erasable programmable read-only memory (EEPROM) mounted on the display module main board 235 and coupled with the processing unit 232.

The display connecting unit 233 is configured to connect with the rack connecting unit (labeled 22 in FIG. 2) directly or through a cable (labeled 220 in FIG. 2), for transmitting and receiving information or commands between the information gathering unit (labeled 21 in FIG. 2) and the processing unit 232. When the display connecting unit 233 connects with the rack connecting unit 22 through the cable 220, the touch display module 23 is able to keep connection with information gathering unit 21 even if the touch display module 23 is drawn out from the receiving slot 25. Therefore, operation information of the system components and input commands could be transmitted in real-time when the touch display module 23 is ejected from the receiving slot 25 and operated by the server manager.

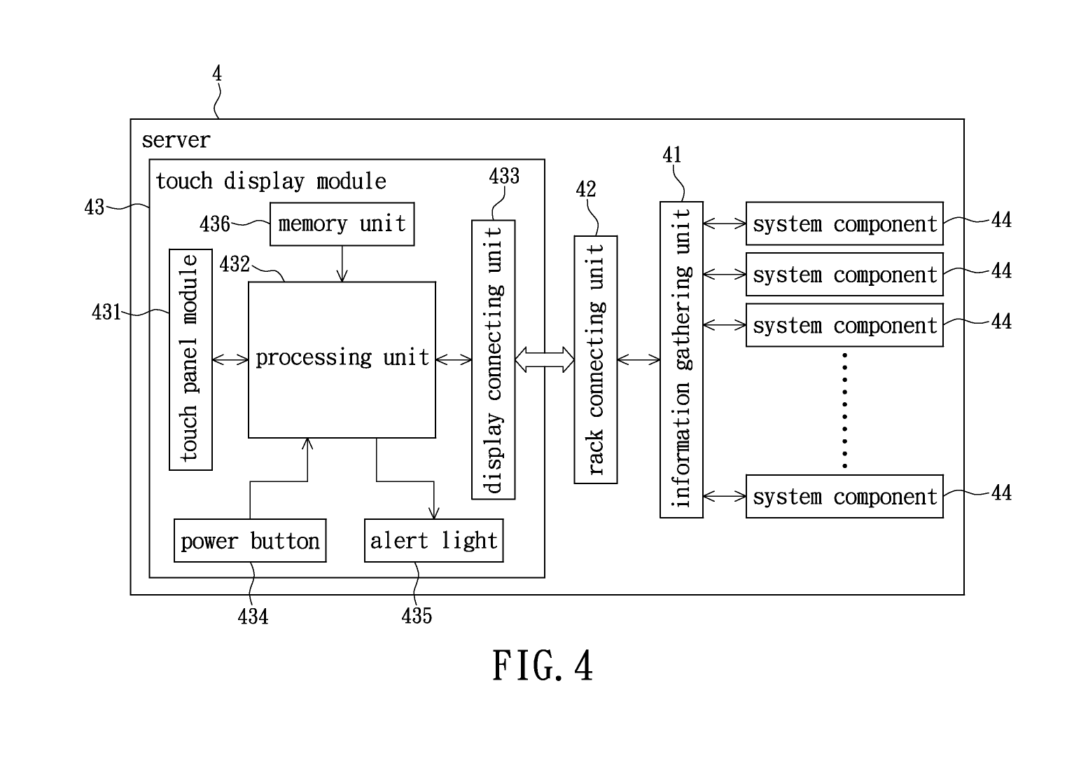

Please refer to FIG. 4, which shows a block diagram of the server in the present embodiment. Elements shown in the block diagram in FIG. 4 correspond to same elements shown in FIG. 2 or 3.

The information gathering unit 41 is connected with a plurality of system components 44 and the rack connecting unit 42 of the server 4, and coupled to the touch display module 43 via the rack connecting unit 42 and the display connecting unit 433 connected therewith. The information gathering unit 41 gathers not only state data from the plurality of system components 44 operating normally, but also gathers error information associated with at least one of the failed or malfunctioned system components 44 to the touch display module 43. Examples of errors occurred in system components 44 may include system component over-heated, failed connection between the system components 44 and the information gathering unit 41, or that the system components are not properly installed in the server.

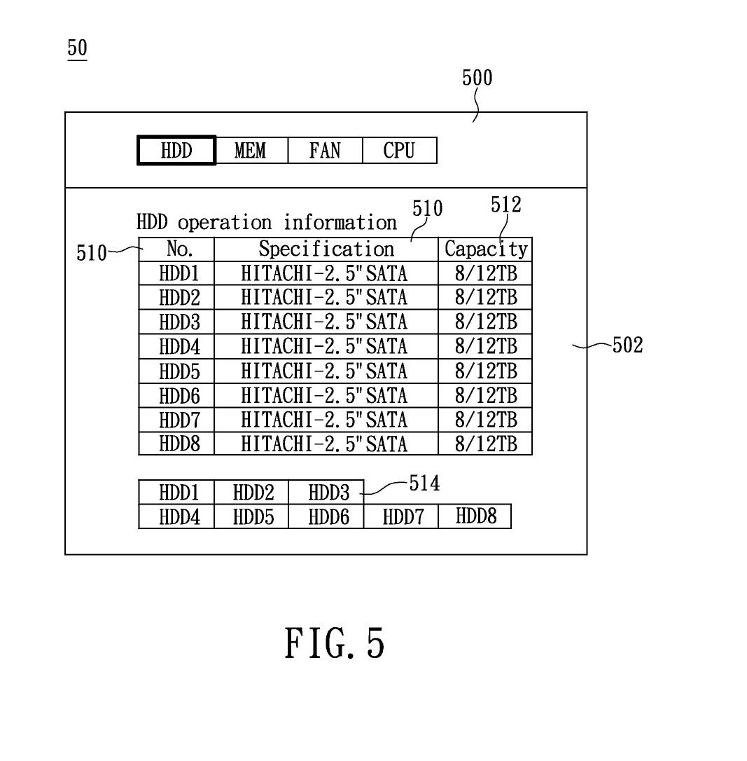

The processing unit 432 of the touch display module 43 may execute a set of programs stored in a memory unit 436 to lay out the operation information in a form of text, table, chart, image, or combination thereof after receiving the operation information gathered by the data gather unit 41. Please refer to FIG. 5, which is an example of showing the operation information on the display panel of the touch panel module 431. The touch panel module 431 may be configured to display categories of the system components of the server in a first area 500 of the display panel 50. The categories may exemplarily include: hard drive (HDD), memory module (MEM), fan, and central processing unit (CPU) and the like for selecting. When one of the categories (e.g. HDD shown in FIG. 5) in the first area 50 is selected by the server manager and detected by the touch detecting module and processed by the processing unit, one or more identification data 510 and state data 512 of the system components of the selected category are shown in text or/and table in a second area 502 below the first area 500, as the serial numbers, the specification, and capacities of the hard drives shown in FIG. 5. Furthermore, along with the text or/and table, icons 514 representing each of the hard drives may also be displayed in the second area 502 to show relative positions of the hard drives. Therefore the server managers may identify the hard drives easily in referring to the text, table, and image on touch panel module 431.

Please to FIG. 4 again. When the received operation information include error information of at least one system component, the processing unit 432 controls the alert light 435 to flash or radiate for attracting the server manager's attention. Except for attracting manager's attention via the alert light 435, when the manager draws out the touch display module 43 and pushes the power button 434 to switch on the display panel, the processing unit 432 of the touch display module 43 outputs an alert message associated with the system component corresponding to the error information to the display panel of the touch display module 431 in addition to identification data of the system components. For instance, the icon representing the system component having errors displayed on the display panel may be marked with a color different to other icons plus additional descriptions.

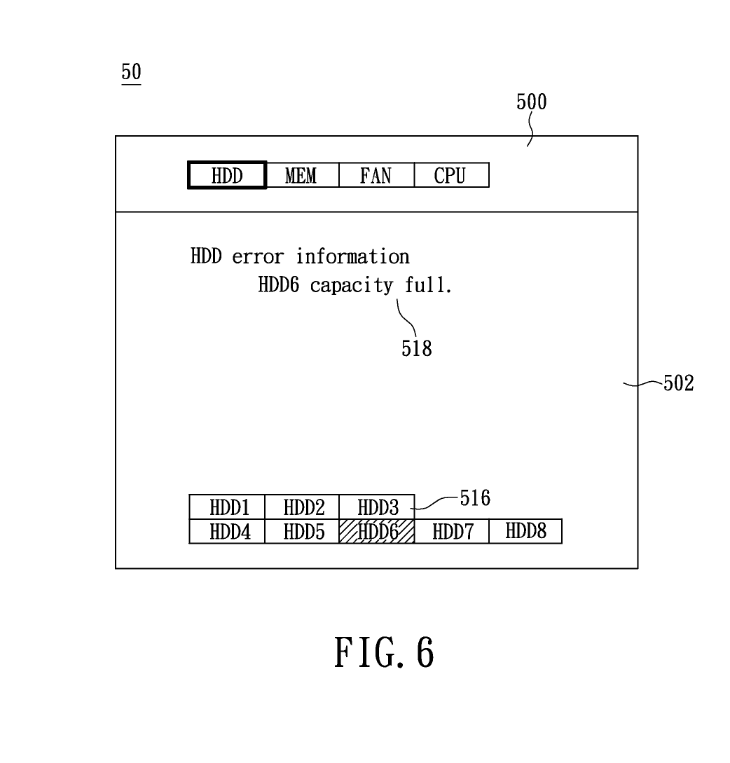

For example, as shown in FIG. 6 which depicts another image displaying the operation information, when the manager chooses to review operation information of hard drives, graphic icons 516 representing hard drives are displayed in the second area 502, wherein the hard drive labeled “HDD6” is marked in a color different to others, and a text alert message is also shown in the second area 502 as part of the error information saying that the storage capacity of HDD6 is full. The alert message 518 is helpful for the server manager to know the identity and the relative position of the failed system component and the problem occurred before uncovering the cover of the rack, which effectively reduce time spending on determining and excluding the problems for the server managers.

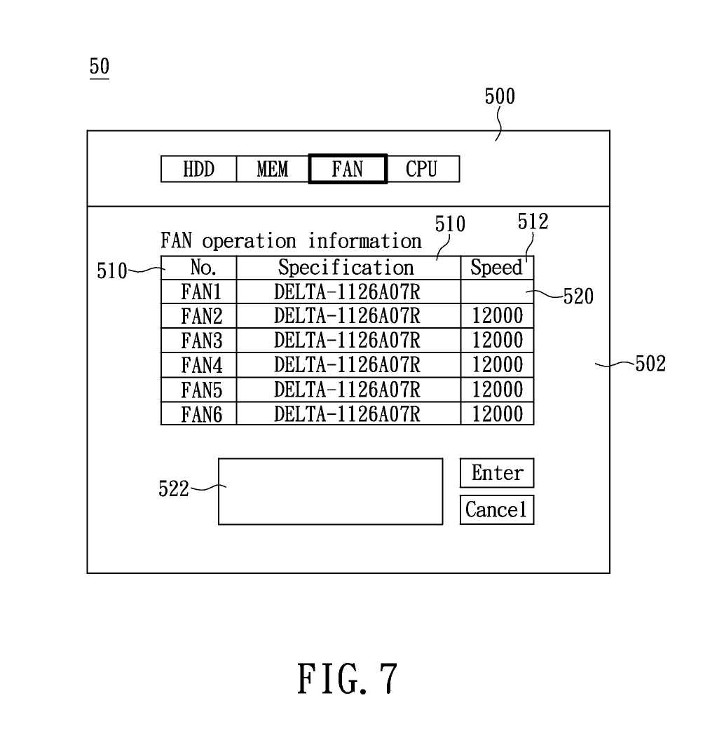

On the other hand, since the touch display module is used in the server of the present embodiment, the touch display module may be configured to be an output device as well as an input device. The server manager may tap or write on the display panel to set status parameters of one or more system components. Please refer to another diagram displaying operation information shown in FIG. 7. The server manager may choose one category of the system components, such as fan, from the first area 500 of the display panel 50. The processing unit of the touch display module would output the identification data 510 (e.g. names, serial numbers, or product type) and state data 512 (e.g. fan speed) of fans installed in the server in the second area 502 according to selection. The state data may include status parameter of the system components, such as the value of the fan speed shown in FIG. 7. The server manager may touch one of the columns on the second area 502, such as the speed column 520 of FAN1 shown in FIG. 7, and input a new fan speed value that the server manager would like to set to FAN1 directly on the column 520 or an input area 522 displayed on the display panel. Referred again to FIG. 4, the processing unit 432 may receive the input command through the touch detecting module (not shown in FIG. 4) of the touch panel module 431, and transmits the input command along with the identification data of the corresponding system component back to the information gathering unit 41 via the display connecting unit 433 and the rack connecting unit 42.

The information gathering unit 41 may feedback the status parameter to the designated system component 44 according to the identification data after receives the input command from the processing unit 432. The designated system component 44 may then be controlled to change the state data according to the status parameter. Take FAN1 shown in FIG. 7 as an example, the information gathering unit 41 may transmit the inputted speed value to a controller of the fan labeled “FAN1” in the server, and thus cause the fan labeled “FAN1” to update the fan speed. Since the information gathering unit 41 is still coupled with FAN1 through the server main board, the updated fan speed of FAN1 can still be gathered and transmitted to be displayed.

Therefore, the server manager may monitor the operation information of every system component in the server by the touch display module of the server, and use the same touch display module of the server to control and update parameters of each system component as well.

According to the illustrated embodiments, the server equipped with touch display module may provide various operation information of a plurality of system components in the server via the touch display module, including identification data and state data of each system component. The server manager may review and confirm the detail of every system component using the touch display module to effectively monitor the server operation.

Specifically speaking, according to the illustrated embodiment of the present disclosure, when the system component is error, the server equipped with touch display module allows the server manager to quickly and precisely be aware of the failed system component through the error information. The server manager doesn't have to wait until the whole server is drawn out from the rack enclosure and uncovered, or refers the LED lights outside the rack in view of the LED light inside the rack to figure out the problem. Therefore, the server equipped with touch display module may save a lot of time for the server manager in looking for the errors, increasing accuracy in determining the exact problem, and hence improve the efficiency of repairing the server from abnormality.

Moreover, providing a receiving slot on the rack for receiving the touch display module may prevent the touch display module from occupying extra space of the rack enclosure. When the server manager needs the touch display module, the touch display module may be pulled or drawn out from the receiving slot for displaying information after the server manager pushes or presses the front panel of the touch display module. When the touch display module is not in-use, the touch display module may be pushed back into the receiving slot again, in order to protect the touch display module and maintain the simplicity of the server.

Furthermore, utilizing a display module having touch input function may be advantaged in preparing both output function and command input function through the same device, which decreases the needs for coupling to external input or output devices and simplifies the preparation for monitoring servers.

Although the present disclosure has been described in considerable detail with reference to certain preferred embodiments thereof, the disclosure is not for limiting the scope of the disclosure. Persons having ordinary skill in the art may make various modifications and changes without departing from the scope and spirit of the disclosure. Therefore, the scope of the appended claims should not be limited to the description of the preferred embodiments described above.

What is claimed is:

1. A server equipped with a touch display module, wherein the server is installed in a rack enclosure, includes:
a rack, having a receiving slot arranged at a front side of the rack;
an information gathering unit, mounted in the rack and connected with a plurality of system components of the server, used for gathering an operation information of the plurality of the system components;
a rack connecting unit, mounted in the rack and connected with the information gathering unit, used for transmitting the operation information;
a touch display module, including:
a base, slidably received in the receiving slot;
a display connecting unit, mounted in the base and used for connecting with the rack connecting unit, wherein the display connecting unit receives the operation information through the rack connecting unit;
a processing unit, mounted in the base and connected with the display connecting unit, used for receiving and processing the operation information transmitted from the display connecting unit;
a touch panel module, arranged at a top side of the base and connected with the processing unit, used for displaying the operation information processed by the processing unit;
wherein the operation information includes identification data and at least a state data of the plurality of the system components, and when the state data includes an error information of the plurality of the system components, the processing unit outputs an alert message associated with the system component corresponding to the error information to the touch panel module.

2. The server as claimed in claim 1, wherein the touch display module further comprises:
a front panel, arranged at a front side of the base, including a power button and an alert light, and the power button and the alert light are connected with the processing unit;
wherein the processing unit enables the alert light when the processing unit receives the state data including the error information.

3. The server as claimed in claim 1, wherein the touch panel module further receives an input command related the identification data of at least one of the plurality of the system components displayed on the touch panel module, wherein the input command is used to adjust a status parameter of the system component, and the processing unit receives the input command and transmits the input command to the information gathering unit through the display connecting unit.

4. The server as claimed in claim 3, wherein the information gathering unit transmits the status parameter to the system component indicated by the input command in order to adjust the indicated system component according to the status parameter.

5. The server as claimed in claim 2, wherein the base received in the receiving slot is ejected from the receiving slot when the front panel is pressed.

6. The server as claimed in claim 5, wherein the base ejected from the receiving slot is pushed back into the receiving slot when the front panel is pressed.

7. The server as claimed in claim 1, wherein the touch display module further comprises:
a memory unit, recording a set of program;
wherein the processing unit executes the set of program to process the operation information of the plurality of the system components, and outputs the identification data and the error information to be displayed on the touch panel module in a form of text, table, chart, image, or combinations thereof.

8. The server as claimed in claim 1, wherein the rack connecting unit connects with the display connecting unit via a cable.

9. A touch display module, disposed in a server of a rack enclosure, comprising:
a base, slidably received in a receiving slot of a rack;
a display connecting unit, mounted in the base and used for transmitting operation information of a plurality of system components of the server;
a processing unit, mounted in the base and connected with the display connecting unit, used for receiving and processing the operation information transmitted from the display connecting unit;
a touch panel module, arranged at a top side of the base and connected with the processing unit, used for displaying the operation information processed by the processing unit;
wherein the operation information includes identification data and at least a state data of the plurality of the system components, and when the state data includes an error information of the plurality of the system components, the processing unit outputs an alert message associated with the system component corresponding to the error information to the touch panel module.

10. The touch display module as claimed in claim 9, further comprising:
a front panel, arranged at a front side of the base, including a power button and an alert light, and the power button and the alert light connected with the processing unit;
wherein the processing unit enables the alert light when the processing unit receives the state data including the error information.

11. The touch display module as claimed in claim 10, wherein the base received in the receiving slot is ejected from the receiving slot when the front panel is pressed.

12. The touch display module as claimed claim 11, wherein the base ejected from the receiving slot is pushed back into the receiving slot when the front panel is pressed.

13. The touch display module as claimed in claim 9, wherein the touch panel module further receives an input command associated with at least one of the plurality of system components displayed on the touch panel module, wherein the input command is used to adjust a status parameter of the associated system component, and the processing unit receives the input command and transmits the input command to the server through the display connecting unit so that the associated system component is adjusted according to the state parameter.

14. The touch display module as claimed in claim 9, further comprising:
a memory unit, recording a set of program;
wherein the processing unit executes the set of program to process the operation information of the plurality of the system components, and outputs the identification data and the error information to be displayed on the touch panel module in a form of text, table, chart, image, or combinations thereof.
